(19) United States
(12) Patent Application Publication
(10) Pub. No.: US 2008/0128012 A1
(43) Pub. Date: Jun. 5, 2008

(54) GROUND SOURCE ENERGY GENERATOR

(76) Inventors: David B. Schick, Queens, NY (US); Sabrina Kemeny, Los Angeles, CA (US)

Correspondence Address: FITZPATRICK CELLA HARPER & SCINTO, 30 ROCKEFELLER PLAZA, NEW YORK, NY, 10112, US

(21) Appl. No.: 11/941,665

(22) Filed: Nov. 16, 2007

Related U.S. Application Data
(60) Provisional application No. 60/859,711, filed on Nov. 17, 2006.
(60) Provisional application No. 60/878,803, filed on Jan. 5, 2007.

(51) Int. Cl. H01L 35/02

(52) U.S. Cl. 136/201; 136/200

(57) ABSTRACT

A method for generating electricity from a ground source. A temperature differential is created across a thermoelectric generator by passing a first fluid that has been maintained at air temperature over one side of the generator, and passing a second fluid that has been maintained at ground temperature over the other side of the generator. Electricity is generated from a voltage induced by the temperature differential across the thermoelectric generator.

### CROSS-REFERENCE TO RELATED APPLICATIONS

This application claims the benefit of priority based on U.S. provisional application No. 60/859,711, filed Nov. 17, 2006, and U.S. provisional application No. 60/878,803, filed Jan. 5, 2007, both of which are hereby incorporated by reference in their entireties, as if fully set forth herein.

### FIELD OF THE INVENTION

The present invention generally relates to systems, methods, apparatuses, and programs for generating energy from a ground source.

### RELATED ART

Electrical energy is, of course, widely used in today's society for the purposes of powering human technologies. Much of the electrical energy in use today is generated from energy sources such as coal, nuclear power, natural gas, hydroelectric power, and petroleum. Such sources can be costly and can have a negative impact on the environment. Because of this, alternative sources of energy have been contemplated and utilized, including solar energy and wind generators. However, these alternative sources also have a number of drawbacks, such as being limited in their efficiency, usefulness, and the amount of power they can provide.

Thermoelectric generators (TEGs), also called thermopiles, are used to generate electricity. In particular TEGs are electrical systems which convert heat energy into electrical energy. The devices typically comprise an array of p and n doped semiconductors, which are connected in a series arrangement by way of metal pads. When one side of the device is maintained at a different temperature from the other, a voltage is induced at these junctions. Although these devices have been well known for many years, they are typically only used when either very high temperature sources are available (for example greater than 100° C.) or when very small amounts of power are required. The primary reason for this is that these devices tend to have very poor efficiencies when the temperature difference is small.

Some prior art systems attempt to generate thermoelectric power from environmental temperature cycles. For example, U.S. Pat. No. 6,914,343 B2 (Hiller et al.) relates to an electric generator system that produces electric power from environmental temperature changes such as occur during a summer day. The generator operates by absorbing heat from the atmosphere during the day, expelling heat to the atmosphere at night, and passing the heat through a thermoelectric module to convert a fraction of the heat into electrical power.

In more detail the Hiller et al. system makes use of hot and cold parts of a cycle by positioning the thermoelectric module between a phase-change mass (such as water and ammonia) and the environment. The phase-change mass partially or completely freezes during the relatively cold part of the cycle, and partially or completely melts during the relatively hot part of the cycle. During the hot part of the cycle, heat flows from the environment through the thermoelectric module into the phase-change mass, generating electric power which is stored in a capacitor or battery. During the cold part of the cycle, heat flows from the phase-change mass back through the module and out to the environment, also generating electric power that is similarly stored. A diode bridge switches the direction of the current between the hot and cold parts of the cycle for charging the capacitor. A resulting temperature differences across a thermoelectric module causes electric potential differences across the module.

While the Hiller et al. system makes use of temperature cycles in the environment (for example daily temperature variations of the atmosphere) to generate thermoelectric power, this phase-change technique is limited in that it requires the temperature of the environment to swing above and below the temperature of the phase-change mass during the course of the relevant time period (e.g., a day). This can greatly limit the efficiency of the system. Furthermore, the Hiller et al. system does not take advantage of the natural temperature differential between the ground and air. The inventor of the subject patent application has found that this natural temperature differential can be used advantageously in creating a temperature difference across a TEG assembly for the purpose of generating electricity.

Other systems use thermoelectric energy devices to convert wasted thermal energy, for example from engine exhaust, into a useful form. For example, U.S. Patent Application Publication No. US 2007/0095379 A1 (Taher et al.) relates to a system including a first fluid passage which receives a hot exhaust stream and is disposed on a side of the thermoelectric device. A plurality of heat pipes focus thermal energy from a fluid flowing through the first passage towards the side of the device. A second fluid passage, disposed on an opposite second side of the device, conducts thermoelectric energy away from the device. The system generates power by exploiting a temperature differential that is created across the thermoelectric device.

It is noted that the Taher et al. system does not take advantage of the natural temperature differential between the ground and air in generating electric power; rather, as discussed above, the Taher et al. system makes use of hot exhaust gas streams in conjunction with thermoelectric power units. Therefore, while the Taher et al. system may be sufficient for use as an electric power source on a variety of different machines (specific examples given include trucks, trains, and boats), the system requires a source of heat exhaust in order to operate. As such, it may not be ideal for use in stationary or remote locations.

U.S. Pat. No. 6,541,139 B1 (Cibuzar) relates to converting waste energy in a septic system to electricity, using potential and kinetic energy created by a waste stream. The system utilizes a temperature difference between the inside and outside of the septic tank to generate electricity from the heat flowing through a thermoelectric module. It is noted that the Cibuzar system, as well, does not take advantage of the temperature differential between the ground and air in generating electric power; the Cibuzar system, in stark contrast, aims to capture electrical energy from a waste stream in a septic system. Therefore, the Cibuzar system requires use of potential and kinetic energy from a moving waste stream from which to generate electricity.

There exists, therefore, a great need for systems and methods for generating electricity in an efficient manner, and which can be used in a wide variety of locations and settings that can take advantage of the natural temperature differential between the ground and air.

### SUMMARY OF THE INVENTION

The present invention provides systems, methods, apparatuses, and programs for generating energy from a ground source.

In accordance with one embodiment of the present invention, there is provided a method for generating electricity. The method includes maintaining a first fluid at air temperature and passing the first fluid over a first side of a thermoelectric generator, and maintaining a second fluid at ground temperature and passing the second fluid over a second side of the thermoelectric generator. The method also includes generating electric power, using the thermoelectric generator, from a difference in temperature between the first fluid passing over the first side of the thermoelectric generator and the second fluid passing over the second side of the thermoelectric generator.

The fluid may be a liquid metal or a fluid with a high level of electrical conductivity. The fluid may be impelled by an electromagnetic pump.

In accordance with one embodiment of the present invention, there is provided a method for generating electricity from a ground source. The method includes creating a temperature differential across a thermoelectric generator by passing a first fluid maintained at air temperature over a first side of the generator and by passing a second fluid maintained at ground temperature over a second side of the generator. The method also includes generating electricity from a voltage induced by the temperature differential across the thermoelectric generator.

In accordance with another embodiment of the present invention, there is provided a system for generating electricity from a ground source. The system includes an air heat exchanger, disposed substantially above ground, through which fluid is passed and brought to air temperature. The system also includes a ground heat exchanger, disposed substantially below ground, through which fluid is passed and brought to ground temperature. A thermoelectric generator unit is also included, through which fluid from the air heat exchanger is passed over one side, and fluid from the ground heat exchanger is passed over an other side. The thermoelectric generator is adapted to generate electricity from a temperature differential of the fluids of each side.

The thermoelectric generator may have at least one fin, for increasing heat transfer between the thermoelectric generator and the fluid. Further, the system may also have at least one pump, adapted to maintain a predetermined flow rate of the fluid through the system. The fluid may be a liquid metal or a fluid with a high level of electrical conductivity, and may also be impelled by an electromagnetic pump.

In accordance with another embodiment of the present invention, there is provided a system for generating electricity from a ground source. A first tank contains fluid and is disposed substantially above ground. A second tank contains fluid, and is disposed substantially below ground and in contact with the first fluid tank. A thermoelectric module is disposed such that one surface of the module is in contact with the fluid from the first tank and another surface of the module is in contact with the fluid from the second tank. The thermoelectric module is adapted to generate electricity from a temperature differential of the fluids from each tank.

The system may further include a fan element, adapted to force air across the first tank. Further, the second tank may be insulated to reduce heat loss. The fluid may be a liquid metal or a fluid with a high level of thermal conductivity.

In accordance with another embodiment of the present invention, there is provided a system for generating electricity from a ground source. A thermoelectric generator unit is disposed substantially above ground and is exposed to air temperature. A ground heat exchanger is disposed substantially below ground, in which fluid is passed over one side of the thermoelectric generator unit. A temperature differential between a side of the thermoelectric generator unit exposed to air and the side of the thermoelectric generator unit in contact with the fluid is created and electricity is generated therefrom.

The system may further include a blower to maintain the flow of air over the thermoelectric generator unit. Further, the thermoelectric generator unit may have at least one fin for transferring heat to and from the air or the fluid. The fluid may be a liquid metal or a fluid with a high level of electrical conductivity.

In accordance with another embodiment of the present invention, there is provided a method for generating electricity from a ground source using a refrigeration cycle. The method includes (a) superheating a refrigerant and using the superheated refrigerant to heat one side of a thermoelectric generator, (b) cooling the refrigerant to ground temperature, (c) supercooling the refrigerant and using the supercooled refrigerant to cool another side of the thermoelectric generator, (d) heating the supercooled refrigerant to air temperature, and (e) generating electricity from a temperature differential across the hot side and the cold side of the thermoelectric generator.

In accordance with another embodiment of the present invention, there is provided a method of generating electricity using a ground source. The method includes (a) creating a temperature difference across a thermoelectric generator using the thermal energy difference between ground and air, and (b) increasing the temperature difference across the thermoelectric generator by using a temperature transformer.

The temperature transformer may use a compression/expansion process, an absorption/evaporation process, or a chemical transformation process.

Further features and advantages of the present invention as well as the structure and operation of various embodiments of the present invention are described in detail below with reference to the accompanying drawings.

### BRIEF DESCRIPTION OF THE DRAWINGS

The features and advantages of the present invention will become more apparent from the detailed description set forth below when taken in conjunction with the drawings in which like reference numbers indicate identical or functionally similar elements.

FIG. 1 illustrates a device for harvesting energy according to one embodiment of the present invention.

FIG. 2 illustrates a side view of a thermoelectric assembly.

FIG. 3 illustrates a front view of the thermoelectric assembly shown in FIG. 2.

FIG. 4 illustrates an arrangement of components for a static reservoir system according to one embodiment of the present invention.

FIG. 5 illustrates an example TEG arrangement for use in conjunction with the system of FIG. 4 which increases the surface area and integrates fins.

FIG. 6 illustrates a block diagram of an air/fluid hybrid system according to another embodiment of the present invention.

FIG. 7 illustrates an example configuration of a TEG optimized for the system of FIG. 6.

FIG. 8 illustrates a block diagram of a refrigeration cycle heat transformer according to another embodiment of the present invention.

### DETAILED DESCRIPTION

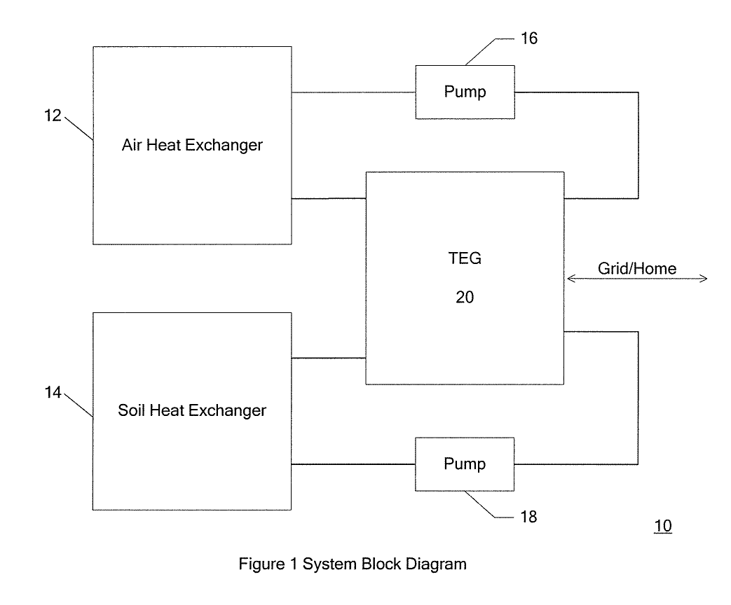

The present invention according to one embodiment is directed to a system for harvesting thermoelectric energy using fluids. FIG. 1 shows a device 10 which harvests energy from the temperature difference between soil and air. At a depth of two meters or greater, the soil temperature of the earth typically remains a fairly stable 8° C., while the air temperature varies with season, climate and time of day.

The device 10 includes an air heat exchanger 12 and a ground heat exchanger 14, both having associated pumps 16, 18, respectively. The device 10 further includes a thermoelectric generator (TEG) assembly 20. Fluid is pumped through the air heat exchanger 12 where it is brought to the air temperature, using either natural or forced convection. At the same time, fluid is pumped through the ground heat exchanger 14 where it is brought to the ground temperature. The ground-side fluid and the air-side fluid are then simultaneously pumped across both sides of the TEG assembly 20. Whenever the air temperature is different from the ground temperature, a temperature difference exists across the TEG assembly 20, and electricity is generated. The fluids are then recirculated through their respective heat exchangers 12, 14, where the heat which is lost or gained in the TEG assembly 20 is replaced. This process operates continuously to provide power.

Because of the typically low efficiencies of the TEG assembly 20, the fluid typically contains much more thermal energy than the desired amount of electricity to be produced. It can therefore be important that the heat exchangers are capable of extracting sufficient power from the air and ground to return the fluid to the desired temperature. For example, if the device 10 operates at 1% efficiency at a temperature difference of 10° C., and the system must produce 1,000 Watts of electricity, then the fluid must contain 100 times that amount of thermal energy, or 100,000 Watts. If the fluid used in this example is water, the system would have to produce a flow rate of approximately 38 gallons per minute. (It is of course to be understood that this is just an example and that the present invention is not limited thereto.) This also means that the air and ground heat exchangers will need to impart 100,000 Watts of thermal energy into the fluid.

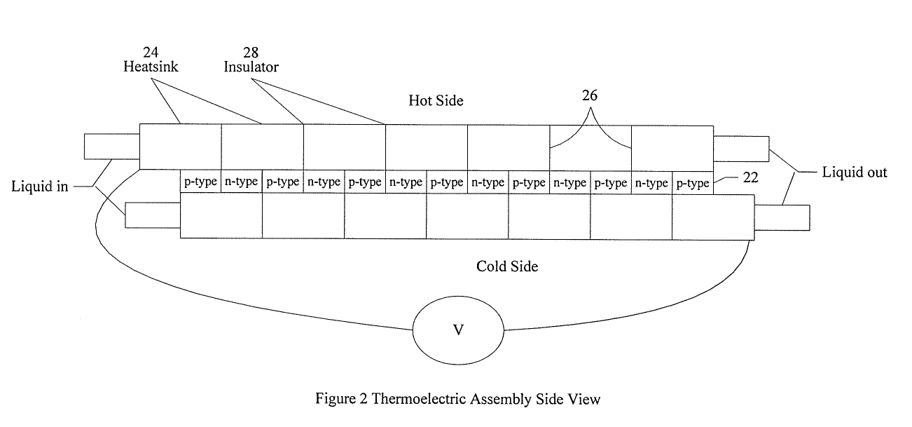

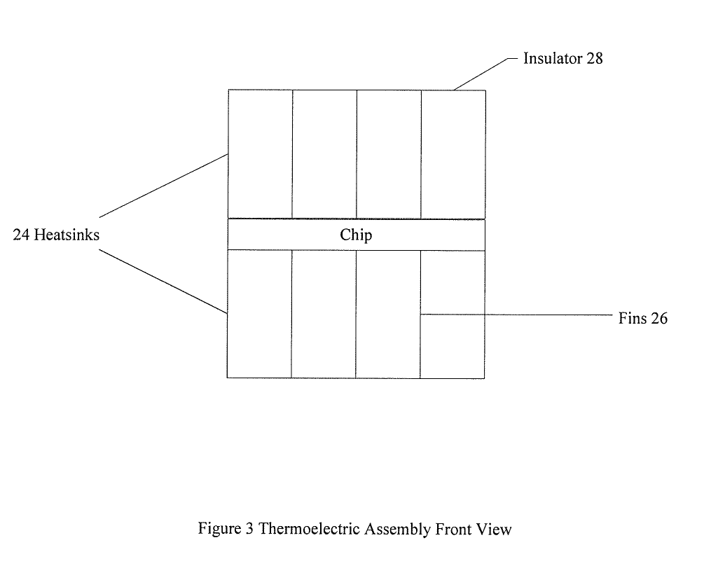

FIGS. 2 and 3 illustrate an implementation of a TEG assembly for use with the system of FIG. 1, which is optimized for efficient transfer of thermal energy from the fluid to the semiconductors. FIG. 2 illustrates a side view of the thermoelectric assembly, and FIG. 3 illustrates a front view of the thermoelectric assembly shown in FIG. 2. In this embodiment, the semiconductor devices 22 are arranged in a straight line of alternating p and n type chips. A series of metallic heat sinks 24 are bonded onto both the top and bottom of the chips 22, in such a manner that each heat sink 24 forms a junction between a p and n chip in the manner shown. The heat sinks 24 can be formed, for example, out of a good thermal and electrical conductor such as copper or aluminum, although the present invention is of course not limited thereto. Each heat sink 24 comprises, in this embodiment, a U-shaped channel with metallic fins 26 extending from the bottom of the U to the top. The heat sinks 24 are bonded together in a line with an electrically insolating epoxy, with the top of the U covered by an insulating material 28. Fluid is pumped through the channel formed by the row of heat sinks 24, and heat is transferred from the fluid to the chips through the fins. Each heat sink 24 also acts as an electrical conductor, which provides a simple, low impedance method for connecting the semiconductor chips in series.

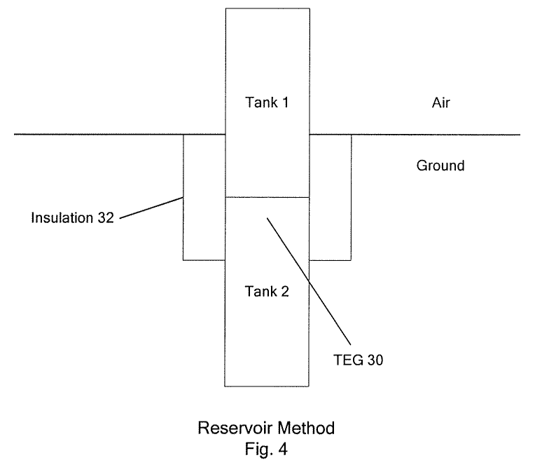

FIG. 4 illustrates an arrangement of components for a static reservoir system according to another embodiment of the present invention. In this configuration, the circulating radiators are replaced by two relatively large fluid tanks, Tanks 1 and 2. One tank (Tank 1) is placed such that most of the tank is in the air, where it can transfer heat to or from the atmosphere. Directly under this tank is a second tank (Tank 2) which is in contact with the ground, where it can transfer heat to or from the earth. In the surface in which the two tanks contact each other, that is, the bottom of Tank 1 and the top of Tank 2, an array of thermo-electric modules (TEG 30) are placed such that one surface of the thermoelectric material is in contact with the fluid from Tank 1, and the other side is in contact with fluid from Tank 2. When there is a difference in temperature between the fluids, electricity is generated.

To improve heat transfer between the tanks and the air and ground, metal fins can be placed around each of the tanks, and the shape of the tanks can be optimized to maximize surface contact with the air and ground. In addition, a fan can be used to force air across tank 1. The fluids within the tanks will circulate due to natural convection; however, it may be desirable to add an agitating pump to increase the movement of the fluids. It may also be advantageous to use a fluid with a high level of thermal conductivity in order to improve the transfer of heat to and from the TEG 30. For example, fluids of high level of thermal conductivity may include, but are not limited to, liquid metals and molten salts.

Since the optimal ground temperature is generally approximately six feet and deeper below the surface, the parts of the tanks which are located between the surface and the optimal temperature point can be insulated (insulation 32) in order to reduce or eliminate heat loss.

The TEG 30 comprises thermoelectric materials which can be optimized for this temperature range (for example, Bi2Te3 or a solid solution of such). It may be desirable to attach metallic heat sinks to the TEG 30 to increase heat transfer between the TEG 30 and the fluids. It may also be desirable to shape the TEG 30 so that it is not flat, in order to increase the surface area of the TEG.

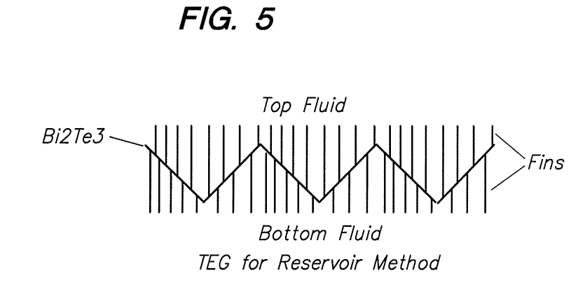

A principal advantage of this configuration is that much less energy can be consumed than pumping the fluid from ground and air radiators. FIG. 5 illustrates an example TEG arrangement for the system of FIG. 4 which increases the surface area and integrates fins.

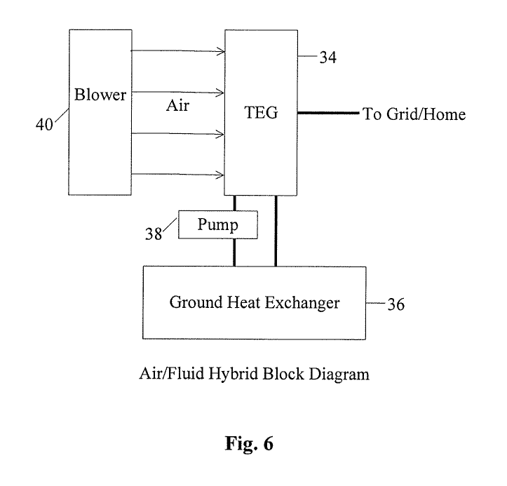

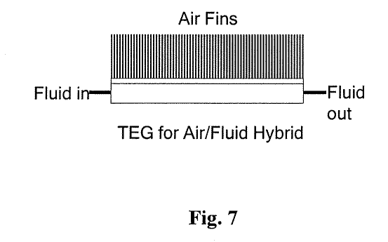

FIG. 6 illustrates a block diagram of an air/fluid hybrid system according to another embodiment of the present invention. In this configuration, a TEG module 34 is located above ground and a below ground radiator (ground heat exchanger 36 associated with pump 38) is used. Air is forced over one side of the TEG 34 with the help of blower 40; it is noted that while blower 40 is shown in the drawings, the present invention is not limited thereto, and other alternatives can be used such as natural convection. The TEG 34 has fins designed to maximize heat transfer to and from the air. Fluid from the ground radiator 36 is flowed across the other side of the TEG 34. When there is a temperature difference between the air and the fluid from the ground radiator 36, electricity is produced. A principal advantage of this configuration is that the circulation of fluid over the air side, and the associated pump, can be eliminated. FIG. 7 illustrates an example configuration of the TEG 34 optimized for this method.

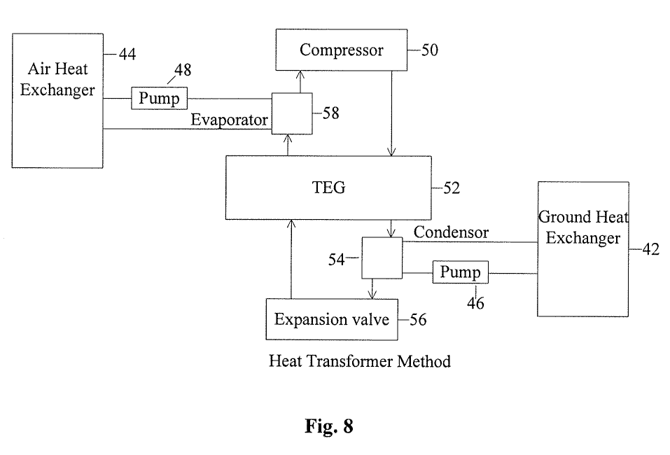

FIG. 8 illustrates a block diagram of a refrigeration cycle heat transformer according to another embodiment of the present invention. In this configuration, the fluid from the ground and air heat exchangers 42, 44 (associated with pumps 46, 48, respectively) are used to transfer heat to and from an intermediate refrigerant. This method takes advantage of the compression/expansion cycle commonly used in refrigeration and air conditioning to increase the temperature differential.

The process works in the following manner. The refrigerant is brought to a high pressure by compressor 50, which raises its temperature to the “superheated” point. It then flows through the TEG 52 where it transfers heat to the ‘hot’ side of the thermoelectric material. It then flows into a heat exchanger (compressor) 54 where it is cooled to the ground temperature. Following this, the refrigerant enters the expansion valve 56 where the pressure is lowered and it is therefore supercooled. It then flows through the ‘cold’ side of the TEG 52 where it absorbs heat from the thermoelectric material. The refrigerant then enters a heat exchanger (evaporator) 58 where it is brought to the air temperature. The cycle is then repeated.

Although perhaps more complex, this method can exhibit a potential efficiency. Because there is a large temperature difference between the superheated and supercooled refrigerant, the TEG 52 can operate at a far higher efficiency level than it would at the relatively low temperature differential of the air and ground. Although losses involved in running the compressor can reduce the efficiency of the overall system, the net efficiency can still be greater, since higher efficiency TEGs can be used at the higher temperature.

In order to optimize the system performance, pressures and temperatures can be dynamically adjusted to track the air to ground temperature. The optimal point is such that the average of the temperatures of the superheated and supercooled refrigerant is equal to the average of the air and ground temperature. This can be done by simply controlling the operating points of the compressor and expansion valve.

As an example, suppose that the air temperature is 22 C and the ground temperature is 8 C; the average is therefore 15C. The compressor superheats the refrigerant to 120 C and the expansion valve supercools the refrigerant to −90 C, meaning that the average is also 10 C. In this example, heat transfer would occur as follows. The superheated refrigerant would exit the compressor 50 and enter the TEG 52 at 120 C. Since the TEG 52 acts as a heat exchanger between the superheated and supercooled refrigerant, the exiting refrigerant would be close to the average temperature, 15 C. The refrigerant exiting the TEG 52 would then pass through the heat exchanger 42 with the ground radiator fluid, which is at 8 C. The flow arrangement would be such that the fluid removes as much heat as possible, so that the refrigerant is brought as close to the ground temperature as possible, 8 C. (This is approximately one half of the energy harvested from the environment.) The refrigerant is then cooled in the expansion valve 2 to −90 C, and flowed into the TEG 52, where it again reaches the average temperature, 15 C. It then goes through a heat exchanger 44 with the air fluid to be brought to the air temperature, 22 C. (This is the point where the other half of the energy is harvested.) The refrigerant is then flowed back into the compressor 50 where the cycle begins again.

In this example, there is approximately a 10× increase in the Carnot efficiency of the system (from 4.9% to 53%). Although this efficiency gain is sacrificed in the added energy of the compressor, the higher differential can enable the use of a converter with a higher ZT. So, for example, if the ZT of the TEG at low temperature is approximately 1, the overall conversion efficiency in this example will be about 1.4%. If the ZT is raised to 2, the efficiency will double to 2.8%. (The theoretical efficiency of the TEG alone will be over 40%.)

Many variations of this method are envisioned, including using other methods of heat transformation (such as absorption/evaporation or a chemical transformation), and using an Air/Fluid hybrid method for the heat exchangers. It is also possible to use methods of energy conversion other than TEGs, such as Stirling engines or steam turbines.

The pumps used in the present invention may be various kinds of pumps suitable for carrying out the methods described herein. In one preferred embodiment, electromagnetic pumps are used. In such pumps, a conductive liquid is made to move through a pipe or channel by sending a large current transversely through the liquid. The current reacts with a magnetic field that is perpendicular to the pipe and to the current flow, to exert force on the current-carrying liquid conductor. In this way, the current-carrying liquid conductor is pumped through the pipe or channel. The conductive liquid may be, for example, an alkali metal in a liquid condition (e.g., potassium), a liquid alloy of an alkali metal, a molten salt, or a eutectic metal alloy in a liquid condition. Of course, the conductive liquid is not limited to these examples. The high electrical conductivity of the liquid metals pumped allows a pumping force to be developed within the metals when they are confined in the pipe or channel and subjected to the magnetic field and to the electric current. Other metallic and nonmetallic liquids of sufficiently high electrical conductivity may also be pumped. The absence of moving parts within the pumped liquid can eliminate the need for seals and bearings that are found in mechanical pumps, thus minimizing leaks and improving reliability. An example of a pump that may be used with the present invention is described in United Kingdom patent No. 344,881 (Einstein et al.), which is hereby incorporated by reference as if fully set forth herein.

The present invention or any part(s) or function(s) thereof may be implemented using hardware, software or a combination thereof and may be implemented in one or more computer systems or other processing systems. It is noted that the various components of the present invention, for example any of the air heat exchangers, the ground heat exchangers, the compressors, the pumps, the TEG assemblies, etc., may be controlled by one or more modules coupled to the various components. The modules can operate in accordance with software control programs and operating routines stored in an associated memory or memories. The modules and their sub-modules can write and/or read information to/from the memory or memories.

In this way, modules can perform operations in accordance with the system, method, and apparatus of the present invention. The modules may be implemented using hardcoded computational modules or other types of circuitry, or a combination of software and circuitry modules. Software routines for performing the modules can, in one embodiment, be stored as instructions in a memory and can be executed by a processor of a control module.

In an embodiment where the invention is implemented using software, the software may be stored in a computer program product, a computer program medium, or a computer usable medium, and loaded into a computer system using a removable storage drive, a hard drive, or a communications interface. The control logic (software), when executed by a processor, causes the processor to perform the functions of the invention as described herein.

In this document, the terms “computer program medium” and “computer usable medium” are used to refer generally to media such as a removable storage drive, a hard disk installed in a hard disk drive, and signals. These computer program products provide software to the system.

While various embodiments of the present invention have been described above, it should be understood that they have been presented by way of example, and not limitation. It will be apparent to persons skilled in the relevant art(s) that various changes in form and detail can be made therein without departing from the spirit and scope of the present invention. Thus, the present invention should not be limited by any of the above-described exemplary embodiments, but should be defined only in accordance with the following claims and their equivalents.

1. A method for generating electricity, comprising the steps of:
maintaining a first fluid at air temperature and passing the first fluid over a first side of a thermoelectric generator;
maintaining a second fluid at ground temperature and passing the second fluid over a second side of the thermoelectric generator; and
generating electric power, using the thermoelectric generator, from a difference in temperature between the first fluid passing over the first side of the thermoelectric generator and the second fluid passing over the second side of the thermoelectric generator.

2. The method as set forth in claim 1, wherein the fluid is a liquid metal or a fluid with a high level of electrical conductivity.

3. The method as set forth in claim 2, wherein the fluid is impelled by an electromagnetic pump.

4. A method for generating electricity from a ground source, comprising the steps of:
creating a temperature differential across a thermoelectric generator by passing a first fluid maintained at air temperature over a first side of the generator and by passing a second fluid maintained at ground temperature over a second side of the generator; and
generating electricity from a voltage induced by the temperature differential across the thermoelectric generator.

5. A system for generating electricity from a ground source, comprising:
an air heat exchanger, disposed substantially above ground, through which fluid is passed and brought to air temperature;
a ground heat exchanger, disposed substantially below ground, through which fluid is passed and brought to ground temperature; and
a thermoelectric generator unit through which fluid from the air heat exchanger is passed over one side, and fluid from the ground heat exchanger is passed over an other side, the thermoelectric generator adapted to generate electricity from a temperature differential of the fluids of each side.

6. The system as set forth in claim 5, wherein the fluid is a liquid metal or a fluid with a high level of electrical conductivity.

7. The system as set forth in claim 6, wherein the fluid is impelled by an electromagnetic pump.

8. The system as set forth in claim 5, wherein at least one pump is adapted to maintain a predetermined flow rate of the fluid through the system.

9. The system as set forth in claim 5, wherein the thermoelectric generator has at least one fin, for increasing heat transfer between the thermoelectric generator and the fluid.

10. A system for generating electricity from a ground source, comprising:
a first tank containing fluid and disposed substantially above ground;
a second tank containing fluid, disposed substantially below ground and in contact with the first fluid tank; and
a thermoelectric module disposed such that one surface of the module is in contact with the fluid from the first tank and another surface of the module is in contact with the fluid from the second tank, the thermoelectric module adapted to generate electricity from a temperature differential of the fluids from each tank.

11. The system as set forth in claim 10, wherein the fluid is a liquid metal or a fluid with a high level of thermal conductivity.

12. The system as set forth in claim 10, further comprising a fan element adapted to force air across the first tank.

13. The system as set forth in claim 10, wherein the second tank is insulated to reduce heat loss.

14. A system for generating electricity from a ground source, comprising:
a thermoelectric generator unit disposed substantially above ground and exposed to air temperature; and
a ground heat exchanger disposed substantially below ground, in which fluid is passed over one side of the thermoelectric generator unit,
wherein a temperature differential between a side of the thermoelectric generator unit exposed to air and the side of the thermoelectric generator unit in contact with the fluid is created and electricity is generated therefrom.

15. The system as set forth in claim 14, further comprising a blower to maintain the flow of air over the thermoelectric generator unit.

16. The system as set forth in claim 14, wherein the fluid is a liquid metal or a fluid with a high level of electrical conductivity.

17. The system as set forth in claim 14, wherein the thermoelectric generator unit has at least one fin for transferring heat to and from the air or the fluid.

18. A method for generating electricity from a ground source using a refrigeration cycle, comprising the steps of:
superheating a refrigerant and using the superheated refrigerant to heat one side of a thermoelectric generator;
cooling the refrigerant to ground temperature;
supercooling the refrigerant and using the supercooled refrigerant to cool another side of the thermoelectric generator;
heating the supercooled refrigerant to air temperature; and
generating electricity from a temperature differential across the hot side and the cold side of the thermoelectric generator.

19. A method of generating electricity using a ground source, comprising the steps of:
creating a temperature difference across a thermoelectric generator using the thermal energy difference between ground and air; and
increasing the temperature difference across the thermoelectric generator by using a temperature transformer.

20. The method as set forth in claim 19, wherein the temperature transformer uses a compression/expansion process.

21. The method as set forth in claim 19, wherein the temperature transformer uses one of an absorption/evaporation process and a chemical transformation process.
